(19) United States
(12) Patent Application Publication
(10) Pub. No.: US 2011/0193837 A1
(43) Pub. Date: Aug. 11, 2011

(54) SUBSTRATE FOR ELECTRO-OPTICAL DEVICES, ELECTRO-OPTICAL DEVICE AND ELECTRONIC APPARATUS

(75) Inventor: Takashi Sato, Chino-shi (JP)

(73) Assignee: Seiko Epson Corporation, Tokyo (JP)

(21) Appl. No.: 13/014,270

(22) Filed: Jan. 26, 2011

(30) Foreign Application Priority Data
Feb. 5, 2010 (JP) 2010-024222

(51) Int. Cl. G09G 5/00; H01L 27/15

(52) U.S. Cl. 345/205; 257/59; 257/E27.121

(57) ABSTRACT

A electro-optical device is provide with a substrate, a pixel electrode, a transistor which is provided more to a lower layer side than the pixel electrode, and a connection electrode which is arranged more to an upper layer side than a gate insulating film, is formed to directly overlap with at least a portion of a gate electrode and a source/drain electrode in a region where the gate insulating film is not formed, and is electrically connected to the transistor.

### CROSS-REFERENCE TO RELATED APPLICATION

This application is based on and claims priority from Japanese Patent Application No. 2010-024222, filed on Feb. 5, 2010, the contents of which are incorporated herein by reference

### BACKGROUND

1. Technical Field

The present invention relates to a substrate for electro-optical devices, an electro-optical device provided with the substrate for electro-optical devices, and an electronic apparatus provided with the electro-optical device.

2. Related Art

As an example of this type of a substrate for electro-optical devices, for example, there is an active matrix substrate which is used in an electro-optical device such as an electrophoretic display device of an active matrix driving method, and is provided with a pixel electrode and scanning lines, data lines, and a thin film transistor (TFT) acting as pixel switching elements for performing selective driving of the pixel electrode, on the substrate. The above constituent elements are formed in a laminated structure on the substrate. Each of the constituent elements is arranged so that each layer is separated and isolated by interlayer insulating films, and are appropriately electrically connected via a contact hole (also called a “through hole”) formed in the interlayer insulating films.

For example, in JP-A-2009-38337, a technology is disclosed for manufacturing organic thin film transistors by applying a material in a limited manner to a region for film deposition using a printing method. According to such a technology, an etching process for forming a contact hole can be reduced.

However, in JP-A-2009-38337 described above, connection wires for electrically connecting between a single or a plurality of transistor terminals are still formed using a method such as etching. As a result, when forming the connection wires, it is necessary to perform film deposition over the entire surface of the substrate, and there is a technical problem in that there are concerns that bending of the substrate may occur due to stress generated in the film. Also, when performing patterning, as a portion of an insulating film, which is formed over the entire surface of the substrate, is discarded and wasted, there is also a technical problem in that this goes against demands for saving resources and lower costs.

### SUMMARY

An advantage of some aspects of the invention is that a substrate for electro-optical devices, which can suppress bending of the substrate while accommodating demands for saving resources and lower costs, an electro-optical device, and an electronic apparatus are provided.

According to an aspect of the invention, there is provided a substrate for electro-optical devices, which has a display region where a plurality of pixels is arranged, including a substrate, a pixel electrode provided for each of the pixels on the substrate, a transistor provided more to a lower layer side than the pixel electrode on the substrate, and a connection electrode which is arranged more to the upper layer side than a gate insulating film configuring the transistor, is formed to directly overlap with at least a portion of a gate electrode and a source/drain electrode of the transistor in a region where the gate insulating film is not formed on the substrate, and is electrically connected to the transistor.

According to the substrate for electro-optical devices of an aspect of the invention, in the display region (also referred to as a pixel region or an image display region as appropriate) where the plurality of pixels is arranged in, for example, a matrix shape, it is possible to realize an image display using a so-called active matrix method by applying image signals to the pixel electrode provided for each pixel.

The “transistor” of an aspect of the invention are provided more to a lower layer side than the pixel electrode on the substrate. The transistor is, for example, a pixel transistor which is provided for each of the pixels and is electrically connected to the pixel electrode. In this case, the transistor is, for example, arranged in the display region where the plurality of pixels is arranged in a matrix shape and makes possible an image display using, for example, a so-called active matrix method by functioning as a switching element for each of the pixels. Also, the transistor may be a periphery transistor which is provided in a peripheral region (that is, a region positioned in the periphery of the display region). In this case, the transistor is used as a circuit element for configuring a driver circuit (that is, an X driver circuit and a Y driver circuit) performing, for example, a relatively rapid switching operation of a driving method with a high driving frequency, a current amplifying operation, a current controlling operation, a rectifying operation, a voltage holding operation and the like. Here, as the purpose of the periphery transistor, there is no limitation so long as it is engaged in the electro-optical operation of the electro-optical device.

The transistor includes a gate insulating film selectively provided in a specific region on the substrate. Here, “selectively provided in a specific region on the substrate” has the meaning of being provided only in a specific region on the substrate, or in other words, provided only on a region of one part of the substrate. For example, the gate insulating film is formed by applying an insulating material in an appropriate region on the substrate using an application method such as an ink jet method. The gate insulating film selectively provided in this manner does not generate wasted materials in the formation process thereof compared to the case where it is formed by laminating an insulating material over the entire surface of the substrate and then performing patterning. As a result, demands for saving resources and lower costs can be accommodated. Also, as the gate insulating film is not formed over the entire surface of the substrate, stress in the substrate can be suppressed.

Here, in the transistor, the gate electrode may be a top gate type arranged more to the upper layer side than the semiconductor layer in the laminate structure on the substrate, the gate electrode may be a bottom gate type arranged more to the lower layer side than the semiconductor layer in the laminate structure on the substrate, or the gate electrode may be a double gate type arranged on both of the upper layer side and the lower layer side of the semiconductor layer.

The “connection electrode” of an aspect of the invention is formed in a region where the gate insulating film is not formed on the substrate. The connection electrode is an electrode to electrically connect the periphery transistor with other conductive layers (for example, various wires, elements or the like for realizing an electro-optical operation which are formed on the substrate). The connection electrode is formed using a conductive material such as aluminum or the like. The region where the connection electrode is formed is in a state where the gate insulating film is not formed and various wires, elements or the like of a conductive layer, which are the connection targets of the connection electrode, are exposed.

In an aspect of the invention, the connection electrode is formed by extending the gate electrode and the source/drain electrode of the transistor. Also, this connection target is at least a portion of the gate electrode and the source/drain electrode of the transistor, the gate electrode and the source/drain electrode of another transistor, or wires such as voltage source lines formed in the same process as the transistor. Here, the gate electrode and the source/drain electrode have the meaning of the actual gate, source and drain of the transistor and the various wires, elements or the like electrically connected to the gate, source and drain. In the region where the connection electrode is formed, at least a portion of the gate electrode and the source/drain electrode, which are connection targets of the connection electrode, are exposed by not forming the gate insulating film. The connection electrode performs electrical connection with the connection targets by being formed on the connection targets exposed in this manner. That is, the connection electrode realizes electrical connection not via the contact hole but by being formed to come into direct contact with the connection targets (namely, there is no laminating structure between it and the connection targets). As connection in this manner does not require performing of a process of making an opening for the contact hole in the gate insulating film by etching or the like, electrical connection can be realized by fewer processes compared to the case of electrical connection via the contact hole. Also, in an aspect of the invention, when electrically connecting the connection electrode to the connection target, as it is not necessary to form the insulating film over the entire surface of the substrate as in the case of forming a contact hole, it is possible to effectively suppress bending (that is, structural warping) of the completed substrate for electro-optical devices.

Here, when forming the gate insulating film, it is good if the gate insulating film is formed by applying a conductive material in an appropriate region on the substrate by an application method such as an ink jet method or the like. In the case where a contact hole is formed in the gate insulating film by patterning, it is necessary to form the insulating film once in a solid form on the substrate and there is more than a little of the insulating film which is wasted when removed by patterning. On the other hand, according to the application method, the gate insulating film can be formed directly in only the necessary region with no waste such as this. Thus, demands for saving resources and lower costs can be accommodated.

As described above, according to an aspect of the invention, it is possible to realize the substrate for electro-optical devices capable of accommodating demands for saving resources and lower costs while suppressing bending of the substrate.

In an aspect of the substrate for electro-optical devices of the invention, it is desirable if the transistor and the connection electrode are provided for each pixel and the pixel electrode are formed to overlap with at least the connection electrode in a planar view above the substrate.

According to an aspect, the transistor is formed as a pixel transistor electrically connected to the pixel electrode, and the pixel electrode is formed to overlap with at least the connection electrode. Since both the connection electrode and the pixel electrode are formed from a conductive material, the connection electrode and the pixel electrode are typically formed by patterning a single conductive film formed widely in a solid form on an element substrate. In this case, since the connection electrode and the pixel electrode are formed from the same film, the size of the pixel electrode is limited by the connection electrode. That is, in the region where the connection electrode is formed, the pixel electrode cannot be formed. On the other hand, according to the embodiment, the pixel electrode is formed to overlap with the connection electrode. As a result, the pixel electrode can be formed widely irrespective of the size or arrangement of the connection electrode.

In another aspect of the substrate for electro-optical devices of the invention, it is desirable if the transistor is arranged in a peripheral region positioned in the periphery of the display region, and the connection electrode is formed to be diode-connected with the transistor.

In another aspect, the connection electrode forms a diode circuit by being formed to electrically connect between, for example, the source and the gate of the transistor.

Also, a plurality of the transistors is provided in the peripheral region positioned in the periphery of the display region, and by being connected to each other by the connection electrode, the plurality of transistors may configure an inverter circuit.

According to an aspect, the inverter circuit can be formed in the peripheral region using, for example, the plurality of transistors.

In another aspect of the substrate for electro-optical devices of the invention, it is desirable if the connection electrode is formed by applying a conductive material in a region where the connection electrode is to be formed.

According to another aspect, the connection electrode is formed by applying a conductive material in an appropriate region on the substrate using an application method such as an ink jet method or the like. In this manner, since the connection electrode is formed not by patterning a single film using etching or the like but are formed by applying a material, there are no wasted materials generated in the formation process thereof. Namely, it is possible to realize the substrate for electro-optical devices capable of accommodating demands for saving resources and lower costs.

In another aspect of the substrate for electro-optical devices of the invention, it is desirable if a plurality of the transistors is provided in the display region or the peripheral region positioned in the periphery of the display region, and the connection electrode is formed by extending the source electrode or the drain electrode of the transistor.

In order to solve the problems described above, the electro-optical device of an aspect of the invention is provided with the substrate for electro-optical devices of the invention described above (each embodiment is included).

According to the electro-optical device of an aspect of the invention, since it is provided with the substrate for electro-optical devices of the invention described above, it is possible to realize various display devices such as an electrophoretic display device, a liquid crystal display device, an organic EL (electro-luminescence) display device which can, for example, perform high quality display.

In order to solve the problems described above, the electronic apparatus of an aspect of the invention is provided with the electro-optical device of the invention described above (each embodiment is included).

According to an aspect of the electronic apparatus of the invention, since it is provided with the electro-optical device of the invention described above, it is possible to realize an electrophoresis device such as electronic paper, an electron emission device (a field emission display and a conduction electron-emitter display), DLP (digital light processing) as a device using the electrophoresis device and the electron emission device, and the like, which can perform high-quality image display. Also, as the electronic apparatus of the invention, it is also possible to realize various electronic apparatuses such as a projection-type display device, a television, a mobile phone, an electronic notebook, a word processor, a video tape recorder of a view finder type or a monitor viewing type, a work station, a TV phone, a POS terminal, a touch panel, a sensor formed in a surface of artificial skin, and the like.

### BRIEF DESCRIPTION OF THE DRAWINGS

The invention will be described with reference to the accompanying drawings, wherein like numbers reference like elements.

FIG. 1 is a block diagram illustrating an entire configuration of an electrophoretic display panel according to a first embodiment.

FIG. 2 is an equivalent circuit diagram illustrating an electrical configuration of a pixel of the electrophoretic display panel according to the first embodiment.

FIG. 3 is an enlarged planar diagram illustrating a configuration of a pixel of the electrophoretic display panel according to the first embodiment.

FIG. 4 is a cross-sectional diagram taken along a line IV-IV of FIG. 3.

FIG. 5 is a circuit diagram illustrating an electrical configuration of a static electricity protection circuit provided in the electrophoretic display panel according to the first embodiment.

FIG. 6 is a circuit diagram illustrating another example of an electrical configuration of the static electricity protection circuit provided in the electrophoretic display panel according to the first embodiment.

FIG. 7 is an enlarged planar diagram of the static electricity protection circuit of the electrophoretic display panel according to the first embodiment.

FIG. 8 is a cross-sectional diagram taken along a line VIII-VIII of FIG. 7.

FIG. 9 is an enlarged cross-sectional diagram of a pixel of the electrophoretic display panel according to a second embodiment.

FIG. 10 is an enlarged cross-sectional diagram of another example of a pixel of the electrophoretic display panel according to the second embodiment.

FIG. 11 is a circuit diagram illustrating an electrical configuration of an inverter circuit provided in a peripheral region of the electrophoretic display panel according to a third embodiment.

FIG. 12 is an enlarged planar diagram of the inverter circuit of the electrophoretic display panel according to the third embodiment.

FIGS. 13A to 13C are process cross-sectional diagrams illustrating a series of manufacturing processes for manufacturing a laminate structure of the peripheral region of the electrophoretic display panel according to the first embodiment.

FIG. 14 is a perspective diagram illustrating a configuration of an electronic paper applied with the electrophoretic display panel of the invention.

FIG. 15 is a perspective diagram illustrating a configuration of an electronic notebook applied with the electrophoretic display panel of the invention.

### DESCRIPTION OF EXEMPLARY EMBODIMENTS

Below, the embodiments of the invention will be described while referring to the diagrams. In the embodiments below, an electrophoretic display panel of a TFT active matrix driving method, which is an example of an electro-optical device provided with an active matrix substrate which is an example of the substrate for electro-optical devices of the invention, is used as an example.

### Electrophoretic Display Panel

### First Embodiment

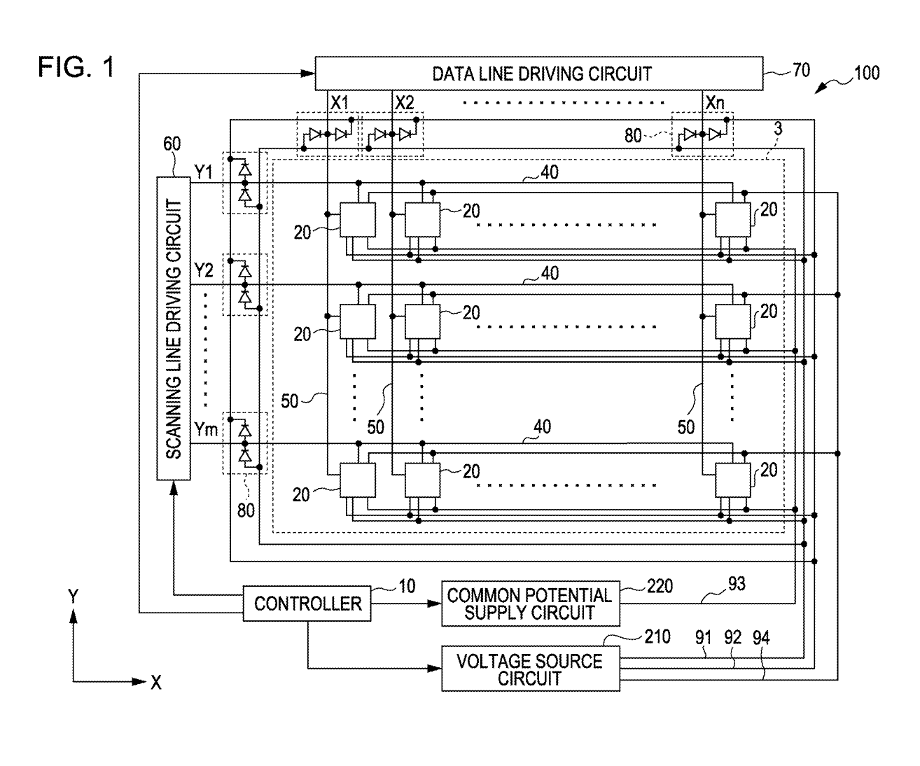

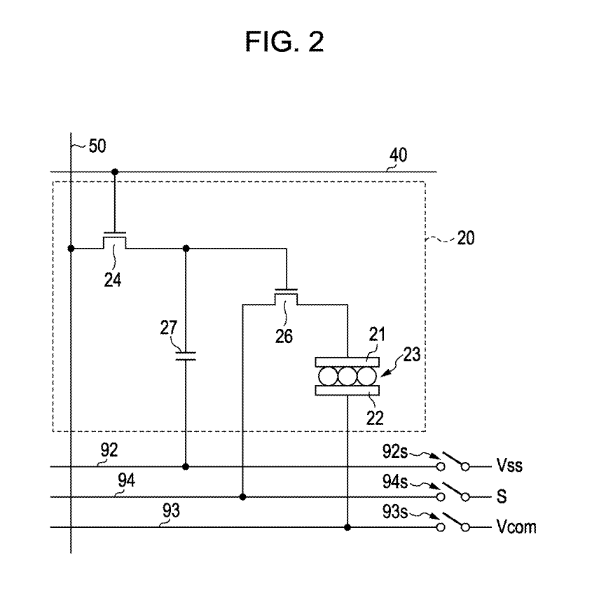

First, an entire configuration of an electrophoretic display panel of the present embodiment will be described with reference to FIGS. 1 and 2.

FIG. 1 is a block diagram illustrating the entire configuration of an electrophoretic display panel of a first embodiment.

In FIG. 1, an electrophoretic display panel 100 of the embodiment is provided with a display unit 3, a controller 10, a scanning line driving circuit 60, a data line driving circuit 70, a voltage source circuit 210, and a common potential supply circuit 220. Here, the display unit 3 is an example of the “display region” of the invention.

In the display unit 3, m rows and n columns of pixels 20 are arranged in a matrix (two dimensional planar) shape. Also, in the display unit 3, m scanning lines 40 (that is, scanning lines Y1, Y2, . . . , Ym) and n data lines 50 (that is, data lines X1, X2, . . . , Xn) are provided to intersect with each other. Specifically, the m scanning lines 40 extend in a row direction (that is, an X direction) and the n data lines 50 extend in a column direction (that is, a Y direction). The pixels 20 are arranged to correspond to the intersections of the m scanning lines 40 and the n data lines 50.

The controller 10 controls the operations of the scanning line driving circuit 60, the data line driving circuit 70, the voltage source circuit 210, and the common potential supply circuit 220. The controller 10 supplies timing signals such as clock signals and start pulse signals to each circuit. Here, the controller 10 also controls the on/off state of switches 92s, 93s, and 94s described later with reference to FIG. 2.

The scanning line driving circuit 60 sequentially supplies scanning signals in pulses to each of the scanning lines Y1, Y2, . . . , Ym based on timing signals supplied from the controller 10.

The data line driving circuit 70 supplies image signals to the data lines X1, X2, . . . , Xn based on timing signals supplied from the controller 10. The image signals take on levels of 2 values, a high level (that is, a high potential level of, for example, 15V) or a low level (that is, a low potential level of, for example, −15V).

The voltage source circuit 210 supplies a high potential voltage source potential Vdd to a high potential voltage source line 91, supplies a low potential voltage source potential Vss to a low potential voltage source line 92, and supplies a control potential S to the control line 94. Also, the common potential circuit 220 supplies a common potential Vcom to a common potential line 93.

The scanning lines 40 and the data lines 50 are electrically connected to a static electricity protection circuit 80 in a peripheral region positioned in a periphery of the display unit 3. The static electricity protection circuit 80 has the function of preventing high voltage pulses (so-called ESD surges) from entering a circuit. Specifically, the static electricity protection circuit 80, for example, channels an ESD surge which has entered an internal portion of a circuit to the high potential voltage source line 91 or the low potential voltage source line 92. As a result, the flowing of the ESD surge into the internal portion of the circuit can be avoided. Here, a specific configuration of the static electricity protection circuit 80 will be described in detail later.

Here, various types of signals are input and output in the controller 10, the scanning line driving circuit 60, the data line driving circuit 70, the voltage source circuit 210, and the common potential supply circuit 220. However, descriptions of signals which have no relation to the embodiment are not included.

FIG. 2 is an equivalent circuit diagram illustrating an electrical configuration of a pixel of the electrophoretic display panel of the embodiment.

In FIG. 2, a pixel 20 is provided with a pixel electrode 21, a common electrode 22 arranged to face the pixel electrode 21, an electrophoresis element 23 provided between the pixel electrode 21 and the common electrode 22, a selection transistor 24, a capacitor 27, and a control transistor 26. Here, the selection transistor 24 and the control transistor 26 are examples of the “transistor” of the invention.

The selection transistor 24 is formed as an N channel type transistor using an amorphous semiconductor. The gate of the selection transistor 24 is electrically connected to the scanning line 40, the source of the selection transistor 24 is electrically connected to the data line 50, and the drain of the selection transistor 24 is electrically connected to the capacitor 27. The selection transistor 24 inputs the image signals supplied from the data line driving circuit 70 (refer to FIG. 1) via the data line 50 to the capacitor 27 at a timing corresponding to the scanning signals supplied in pulses from the scanning lines driving circuit 60 (refer to FIG. 1) via the scanning line 40. Due to this, the image signals are written into the capacitor 27.

The capacitor 27 is a capacitance element for holding the image signals. One of the capacitance electrodes of the capacitor 27 is electrically connected to the drain of the selection transistor 24 and the gate of the control transistor 26. The other capacitance electrode of the capacitor 27 is electrically connected to the low potential voltage source line 92.

The low potential voltage source line 92 is configured to be able to supply the low potential voltage source potential Vss from the voltage source circuit 210 (refer to FIG. 1). The low potential voltage source line 92 is electrically connected to the voltage source circuit 210 via the switch 92s. The switch 92s is configured to be switched between an on state and an off state by the controller 10 (refer to FIG. 1). The low potential voltage source line 92 and the voltage source circuit 210 are electrically connected by making the switch 92s be in the on state, and the low potential voltage source circuit 92 is in an electrically-disconnected high impedance state by making the switch 92s be in the off state.

The control transistor 26 is formed as an N channel type transistor using an amorphous semiconductor. The gate of the control transistor 26 is electrically connected to the capacitor 27 and the drain of the selection transistor 24, the source of the control transistor 26 is electrically connected to the control line 94, and the drain of the control transistor 26 is electrically connected to the pixel electrode 21. The control transistor 26 outputs the control potential S supplied from the voltage source circuit 210 (refer to FIG. 1) via the control line 94 to the pixel electrode 21 according to the potential of the image signals held in the capacitor 27. For example, in the case that the image signal held at the capacitor 27 is a high level, the control transistor 26 is in an on state and the control potential S from the control line 94 is supplied to the pixel electrode 21 via the control transistor 26 which is in the on state. On the other hand, in the case that the image signal held at the capacitor 27 is a low level, the control transistor 26 is in an off state and between the control line 94 and the pixel electrode 21 is electrically disconnected by the control transistor 26 which is in the off state.

The pixel electrode 21 is arranged to face the common electrode 22 through the electrophoresis element 23.

The common electrode 22 is electrically connected to the common potential line 93 which supplies the common potential Vcom. The common potential line 93 is configured to be able to supply the common potential Vcom from the common potential supply circuit 220 (refer to FIG. 1). The common potential line 93 is electrically connected to the common potential supply circuit 220 via the switch 93s. The switch 93s is configured to be switched between an on state and an off state by the controller 10. The common potential line 93 and the common potential supply circuit 220 are electrically connected by making the switch 93s be in the on state, and the common potential line 93 is in an electrically-disconnected high impedance state by making the switch 93s be in the off state.

The electrophoresis element 23 is configured from a plurality of microcapsules which each include an electrophoresis particle. The microcapsules have enclosed, for example, a dispersion medium inside of the capsule, a plurality of white particles and a plurality of black particles. The capsule functions as the outer shell of the microcapsule and is formed from an acrylic resin such as polymethyl methacrylate or polyethyl ethacrylate, or a transparent polymer resin such as urea resin or gum Arabic. The dispersion medium is a medium dispersing the white particles and the black particles in the microcapsules (in other words, in the capsule) and water, alcohol based solvents such as methanol, ethanol, isopropanol, butanol, octanol, or methyl cellosolve, various types of esters such as ethyl acetate or butyl acetate, ketones such as acetone, methyl ethyl ketone or methyl isobutyl ketone, aliphatic hydrocarbons such as pentane, hexane, or octane, alicyclic hydrocarbons such as cyclohexane or methylcyclohexane, aromatic hydrocarbons such as benzene, toluene, xylene or benzenes with a long-chain alkyl group such as hexyl benzene, heptyl benzene, octyl benzene, nonyl benzene, decyl benzene, undecyl benzene, dodecyl benzene, tridecyl benzene or tetradecyl benzene, halogenated hydrocarbons such as methylene chloride, chloroform, carbon tetrachloride or 1,2-dichloroethane, carboxylate or other oils, can be used singularly or in combination. Also, in the dispersion medium, a surfactant may be included. The white particles are particles (polymer or colloid) of a white pigment such as titanium dioxide, zinc oxide or antimony trioxide, and for example, are negatively charged. The black particles are particles (polymer or colloid) of a black pigment such as aniline black or carbon black, and for example, are positively charged. As a result, the white particles and the black particles can be moved within the dispersion medium using an electrical field generated by a difference in potential between the pixel electrode 9 and the opposing electrode 21.

Here, in these pigments, electrolytes, surfactants, metallic soaps, resins, rubber, oils, varnishes, charge control agents formed from particles such as compounds, dispersants such as titanium-based coupling agents, aluminum-based coupling agents and silane-based coupling agents, lubricants, stabilizers and the like can be added as required.

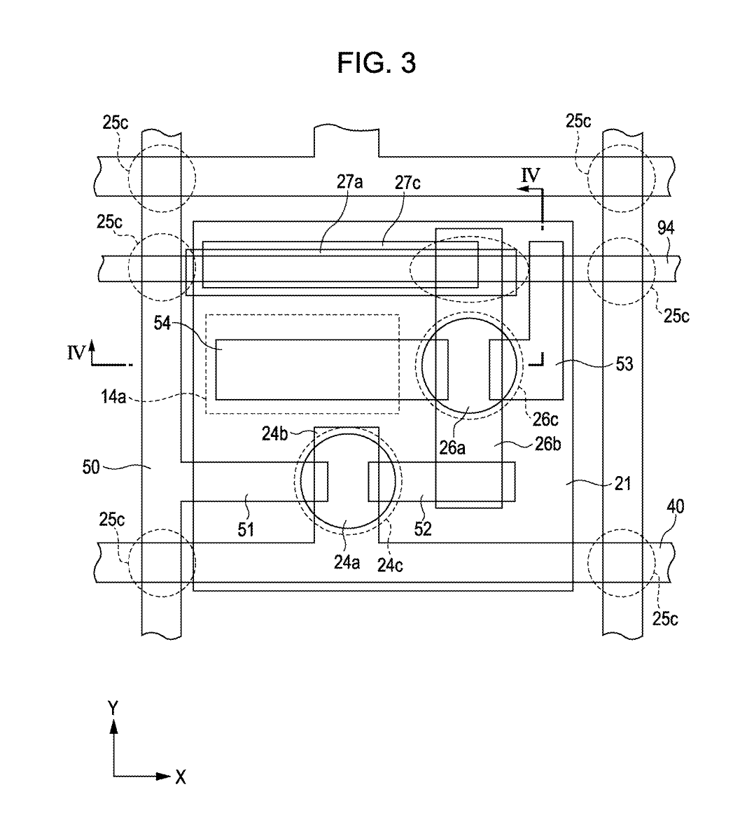

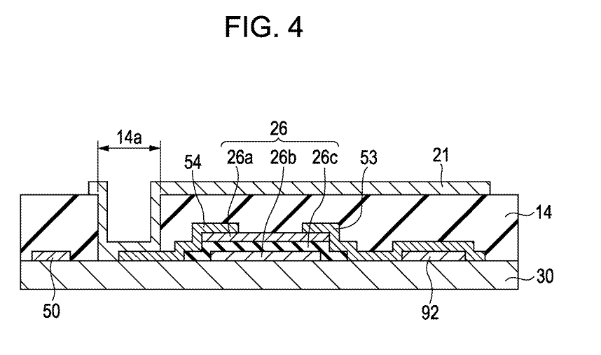

Next, a specific configuration of the pixel 20 of the electrophoretic display panel 100 of the embodiment will be described with reference to FIGS. 3 and 4.

FIG. 3 is an enlarged planar diagram illustrating a configuration of the pixel 20 of the electrophoretic display panel 100 of the embodiment. FIG. 4 is a cross-sectional diagram taken along a line IV-IV of FIG. 3. Here, in FIGS. 3 and 4, since the size of each layer and each member is set to an extent so that they can be recognized in the diagram, the scale for each layer and each member may differ.

In FIG. 3, the selection transistor 24 is configured from a semiconductor layer 24a, a gate electrode 24b and a gate insulating film 24c. The selection transistor 24 is a bottom gate transistor where the gate electrode 24b, the gate insulating film 24c and the semiconductor layer 24a are laminated in that order from the lower layer side.

In FIGS. 3 and 4, the control transistor 26 is configured from a semiconductor layer 26a, a gate electrode 26b and a gate insulating film 26c. The control transistor 26 is a bottom gate transistor where the gate electrode 26b, the gate insulating film 26c and the semiconductor layer 26a are laminated in that order from the lower layer side.

Here, the selection transistor 24 and the control transistor 26 are examples of the “transistor” of the invention.

In FIG. 3, the gate electrode 24b of the selection transistor 24 is integrally formed with the scanning line 40 (that is, as a portion of the scanning line 40). In the embodiment, when seen from a planar view above the element substrate 30, in the scanning line 40 formed mainly along the X direction, a portion of the scanning line 40 formed to partially protrude in the Y direction functions as the gate electrode 24b in one region overlapping with the semiconductor layer 24a. The gate insulating film 24c is provided on the upper layer side of the gate electrode 24b, and the region of the semiconductor layer 24a which faces the gate electrode 24b functions as a channel.

A source electrode 51 of the selection transistor 24 is integrally formed with the data line 50 formed on the element substrate 30 (that is, as a portion of the data line 50). In the embodiment, in the data line 50 formed to extend mainly along the Y direction, a portion formed to partially protrude in the X direction forms the source electrode 51.

The drain of the selection transistor 24 is electrically connected to a first connection electrode 52 which is an example of the “connection electrode” in the invention. The first connection electrode 52 is formed by extending the drain electrode of the selection transistor 24 and also functions as a drain electrode. The connection electrodes below are also provided by extending the source electrode, the gate electrode or the drain electrode, but the description of this is not included. The first connection electrode 52 is electrically connected to the gate electrode 26b of the control transistor 26 described later. Here, the first connection electrode 52 is formed to come into direct contact with the gate electrode 26b. That is, the first connection electrode 52 is electrically connected to the gate electrode 26b without going through a contact hole.

The source of the control transistor 26 is electrically connected to a second connection electrode 53 which is an example of the “connection electrode” in the invention. The second connection electrode 53 is electrically connected to the control line 94 formed to extend along the X direction. Here, the second connection electrode 53 is formed to come into direct contact with the control line 94. That is, the second connection electrode 53 is electrically connected to the control line 94 without going through a contact hole.

The drain of the control transistor 26 is electrically connected to a third connection electrode 54 which is an example of the “connection electrode” in the invention.

Here, an interlayer insulating film 14 is provided on an upper layer side of the laminate structure described above. In the embodiment, in particular, in a planar view above the element substrate 30, the interlayer insulating film 14 is formed to exclude a region 14a surrounded by the dotted line. That is, the third connection electrode 54 in the region 14a is formed to be partially exposed from the interlayer insulating film 14.

The pixel electrode 21 is provided on the interlayer insulating film 14. The pixel electrode 21 is formed widely at the pixel 20 partitioned by the scanning lines 40 and the data lines 50. The pixel electrode 21 is electrically connected by coming into direct contact with the third connection electrode 54 which is partially exposed from the interlayer insulating film 14 in the region 14a. That is, the drain of the control transistor 26 is relayed with the third connection electrode 54 and electrically connected to the pixel electrode 21. Due to this, a voltage supplied from the control line 94 is relayed with the third connection electrode 54 and supplied to the pixel electrode 21 at a timing when a high level signal is supplied to the gate electrode 26b from the drain of the selection transistor 24 (that is, a timing when the control transistor 26 is in the on state).

The connection electrodes are connected to other wires or electrodes not via a contact hole, that is, not via an electrode for connection. Also, since the connection electrodes are formed between the pixel electrode 21 and the element substrate 30, the pixel electrode 21 can be provided over a wide area.

The gate electrode 26b of the control electrode 26 is electrically connected to a capacitance electrode 27a which is an example of the “connection electrode” in the invention. The capacitance electrode 27a is configured as the capacitor 27 by being arranged to face the low potential voltage source line 92 through a capacitance insulating film 27c.

Here, the capacitance electrode 27a is formed to come into direct contact with the gate electrode 26b. That is, the capacitance electrode 27a is electrically connected to the gate electrode 26b without going through a contact hole.

An insulating film 25c, which is formed simultaneously with the gate insulating film 24c, is provided at the intersection of the data line 50, scanning line 40, control line 94 or the low potential voltage source line 92 and the intersection of the gate electrode 26b and the control line 94.

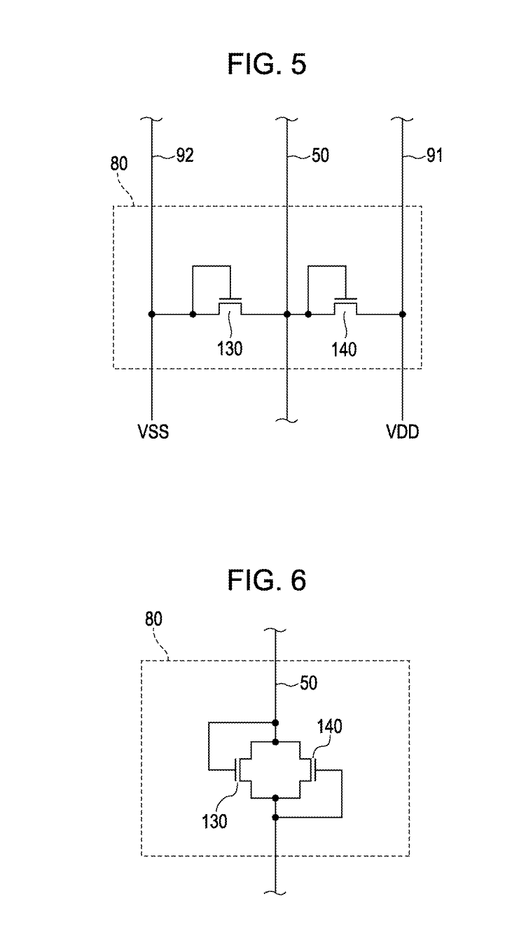

Next, the specific configuration of the static electricity protection circuit 80 formed in the peripheral region will be described with reference to FIG. 5.

FIG. 5 is a circuit diagram illustrating the electrical configuration of the static electricity protection circuit 80 provided in the electrophoretic display panel 100 of the embodiment.

The static electricity protection circuit 80 is provided with a first transistor 130 and a second transistor 140 which are diode-connected.

The source of the first transistor 130 is electrically connected to the data line 50, and the gate and the drain of the first transistor 130 electrically short-circuit each other and are held at the potential Vss by being electrically connected to the low potential voltage source line 92. On the other hand, the source of the second transistor 140 is electrically connected to the high potential voltage source line 91 and is held at the potential Vdd, and the gate and the drain of the second transistor 140 electrically short-circuit each other and are electrically connected to the data line 50. By providing the first transistor 130 and the second transistor 140, which are diode-connected in this manner, to be biased in a reverse direction, current leakage can be suppressed when static electricity is not generated. In addition, in the case when electrostatic discharge (ESD) generates an ESD surge which is applied to the data line 50 and the potential thereof exceeds that of the two voltage source lines 91 and 92, the ESD surge can be swiftly discharged to the two voltage source lines 91 and 92 via the first transistor 130 and the second transistor 140. Accordingly, the static electricity protection circuit 80 can prevent static electricity breakage of the internal circuits (for example, the circuit elements of the TFT and the like of the display unit 3 and the data lines driving circuit 70 in the peripheral region) due to the ESD surge being applied to the data line 50. Here, also the static electricity protection circuit 80 electrically connected to the scanning line 40, by the same mechanism as the static electricity protection circuit 80 electrically connected to the data line 50 described above, can prevent static electricity breakage of the internal circuits due to the ESD surge being applied to the scanning line 40.

Here, the static electricity protection circuit 80 may have the circuit configuration shown in FIG. 6. FIG. 6 is a circuit diagram illustrating another example of an electrical configuration of the static electricity protection circuit 80 provided in the electrophoretic display panel 100 of the embodiment. The static electricity protection circuit 80 of FIG. 6 has two connection terminals, one of the connection terminals is connected to the data line 50 or the scanning line 40 and the other connection terminal is connected to a common line (not shown). For example, in the configuration of FIGS. 1 and 5, the high potential voltage source line 91 is the common line, and the circuit of FIG. 6 is used instead of a diode 140. In this case, the low potential voltage source line 92 may not be provided. In the common line, a common potential, for example 0V, is applied.

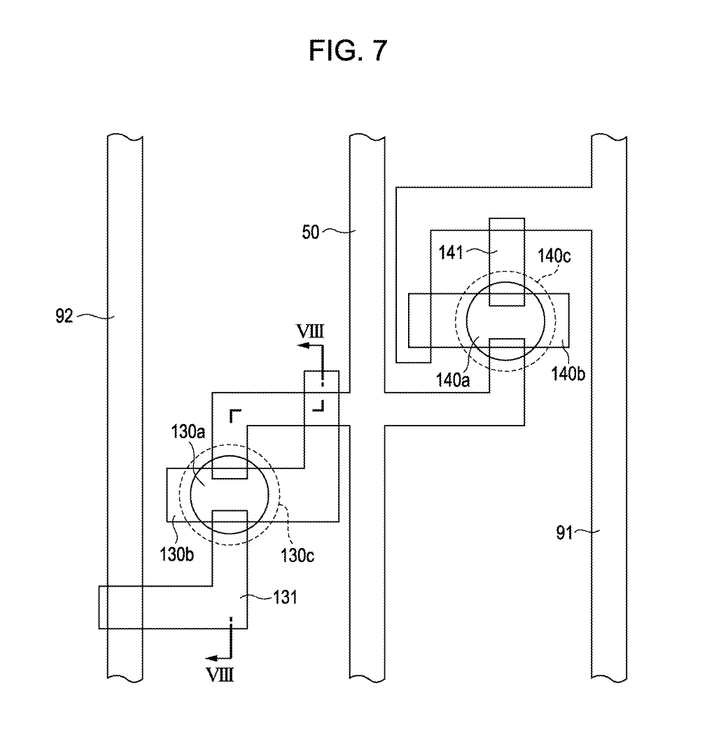

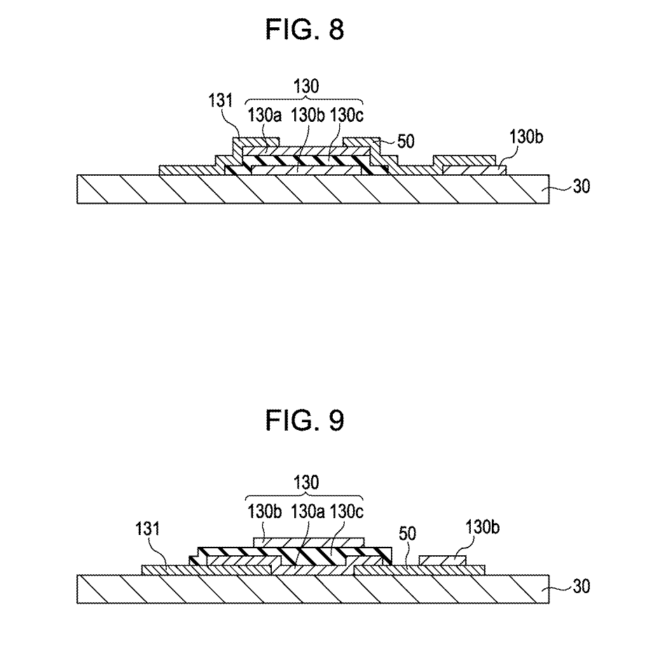

Next, the specific configuration of the static electricity protection circuit 80 of the peripheral region of the electrophoretic display panel 100 of the embodiment will be described with reference to FIGS. 7 and 8.

FIG. 7 is an enlarged planar diagram of the static electricity protection circuit 80 of the electrophoretic display panel 100 of the embodiment. FIG. 8 is a cross-sectional diagram taken along a line VIII-VIII of FIG. 7. Here, in FIGS. 7 and 8, since the size of each layer and each member is set to an extent so that they can be recognized in the diagram, the scale for each layer and each member may differ.

In FIGS. 7 and 8, the first transistor 130 is configured by a gate electrode 130b being arranged to face a semiconductor layer 130a through a gate insulating film 130c.

The source of the first transistor 130 is electrically connected to the low potential voltage source line 92 via a first connection line 131 which functions as a source electrode. Here, the first connection line 131 is an example of the “connection electrode” of the invention and is formed to come into direct contact with the low potential voltage line 92. That is, the first connection line 131 is electrically connected to the low potential voltage source line 92 without going through a contact hole.

The gate electrode 130b of the first transistor 130 is electrically connected to the data line 50 by being formed to extend to the data line 50. Here, the gate electrode 130b is an example of the “connection electrode” of the invention and is formed to come into direct contact with the data line 50. That is, the gate electrode 130b is electrically connected to the data line 50 without going through a contact hole.

In the drain of the first transistor 130, the data line 50 is connected to be partially extended.

The second transistor 140 is configured by a gate electrode 140b being arranged to face a semiconductor layer 140a through a gate insulating film 140c.

In the source of the second transistor 140, the data line 50 is connected to be partially extended and this portion of the data line 50 functions as a source electrode.

The gate electrode 140b of the second transistor 140 is electrically connected a portion formed from a partial extension of the high potential voltage source line 91. The portion formed from the extension of the high potential voltage source line 91 is also electrically connected to a second connection line 141 connected to the drain of the second transistor 140. Here, the second connection line 141 is an example of the “connection electrode” of the invention and is formed to come into direct contact with the high potential voltage source line 91. That is, the second connection line 141 is electrically connected to the high potential voltage source line 91 without going through a contact hole. The high potential voltage source line 91 and the low potential voltage source line 92 are formed in the same process as the data lines 50.

As described above, according to the embodiment, it is possible to accommodate demands for saving resources and lower costs while suppressing bending of the substrate by directly forming the connection electrodes at the connection targets. Also, the pixel electrodes can be formed widely in the pixels by forming the connection electrodes to overlap with the pixel electrodes. As a result, it is possible to realize an electrophoretic display panel capable of high-quality image display.

### Second Embodiment

Next, an electrophoretic display panel according to a second embodiment will be described with reference to FIG. 9.

FIG. 9 is an enlarged cross-sectional diagram of a TFT substrate of the electrophoretic display panel of the embodiment. In the first embodiment described above, the case where the static electricity protection circuit 80 with a bottom gate type transistor which is diode-connected is provided in the peripheral region is exemplified. However, in the present embodiment, the case where the static electricity protection circuit 80 with a top gate type transistor which is diode-connected is provided in the peripheral region is exemplified. Here, since the electrophoretic display panel of the embodiment has the same basic configuration as the electrophoretic display panel of the first embodiment, the same members have the same reference numerals attached and a detailed description is not repeated.

The first connection line 131 and the data line 50 are formed on the element substrate 30. The semiconductor layer 130a is formed to come into contact with each of the end portions of the first connection line 131 and the data line 50. Furthermore, on the upper layer side, the gate insulating film 130c and the gate electrode 130b are provided and a selection transistor 130 is configured as a top gate type transistor.

Also, on the data line 50, a portion, which is formed by extending the gate electrode 130b which is an example of the “connection electrode” of the invention, is provided so as to come into direct contact. Accordingly, the gate electrode 130b is electrically connected to the data line 50 without going through a contact hole.

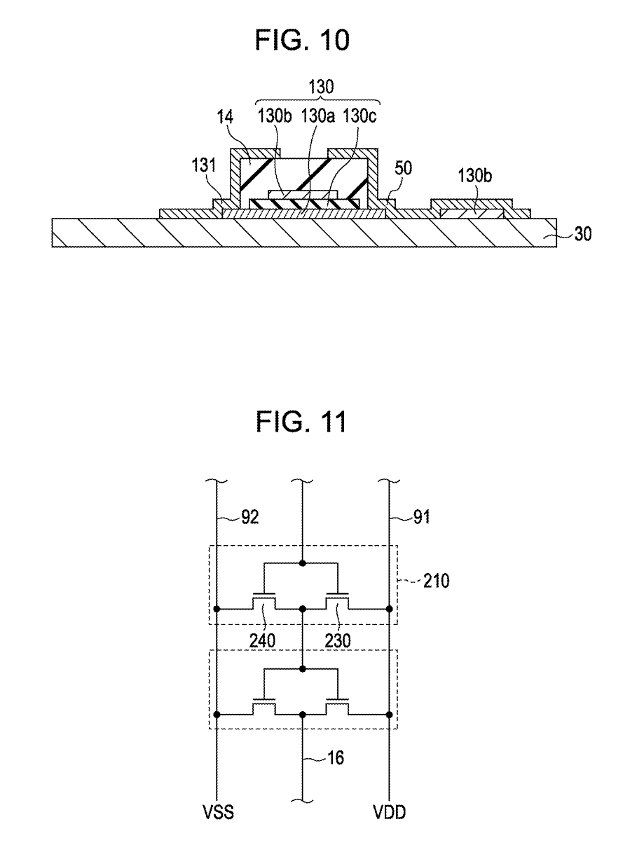

Here, in the case when the first transistor 130 has a top gate type structure, it may have a laminate structure shown in FIG. 10. FIG. 10 is a diagram illustrating another structure of a top gate type TFT.

In FIG. 10, the semiconductor layer 130a is formed on a base film 12. On the upper layer side of the semiconductor layer 130a, the gate insulating film 130c is formed to expose a region of the semiconductor layer 130a where the source and the drain are to be formed. The gate electrode 130b is formed on the gate insulating film 130c and a region of the semiconductor layer 130a facing the gate electrode 130b is configured to function as a channel. The interlayer insulating film 14 is formed on the gate electrode 130b. Here, the interlayer insulating film 14 is formed to expose the region of the semiconductor layer 130a where the source and the drain are to be formed in the same manner as the gate insulating film 130c, and furthermore, the interlayer insulating film 14 is arranged to be interposed between the data line 50 and the first connection line 131 formed on the upper layer side.

In the exposed region of the semiconductor layer 130a where the source and the drain are to be formed, the data line 50 and the first connection line 131 are formed to come into direct contact. Also, the data line 50 is formed to come into direct contact also with a portion of the gate electrode 130b which extends onto the base layer 12. That is, in the embodiment, the data line 50 and the first connection line 131 are examples of the “connection electrodes” of the invention.

### Third Embodiment

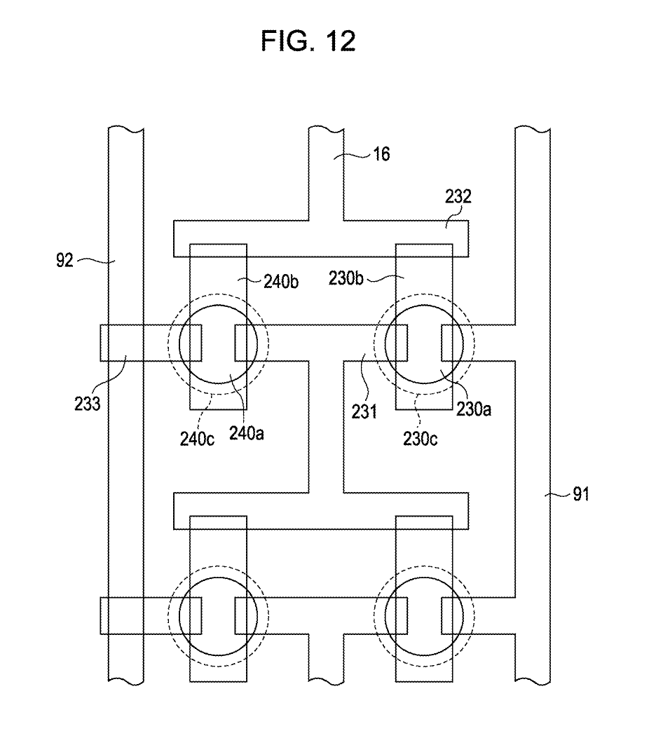

Next, an electrophoretic display panel according to a third embodiment will be described with reference to FIGS. 11 and 12. In the first and second embodiments described above, the case where the static electricity protection circuit 80 with a transistor which is diode-connected is provided in the peripheral region is exemplified. However, the present embodiment is different in that an inverter circuit is provided in the peripheral region. Here, since the electrophoretic display panel of the embodiment has the same basic configuration as the electrophoretic display panel of the embodiments described above, the same members have the same reference numerals attached and a detailed description is not repeated.

First, with reference to FIG. 11, the electrical configuration of an inverter circuit 210 provided in the peripheral region of the electrophoretic display panel of the embodiment will be described. FIG. 11 is a circuit diagram illustrating the electrical configuration of the inverter circuit 210 provided in the peripheral region of the electrophoretic display panel of the embodiment. Here, in FIG. 11, an appearance, where a plurality of the same inverter circuits is connected, is diagrammatically shown, but below, only one inverter circuit 210 will be described as representative and description of the other inverter circuits will not be included.

In FIG. 11, the circuit surrounded by the dotted line is one inverter circuit 210. The inverter circuit 210 is configured by a first transistor 230 and a second transistor 240.

The first transistor 230 is a P channel type transistor, and the second transistor 240 is an N channel type transistor.

The source of the first transistor 230 is electrically connected to the high potential voltage source line 91. On the other hand, the source of the second transistor 240 is electrically connected to the low potential voltage source line 92. The gate and the drain of the first transistor 230 are electrically short-circuited to each of the gate and the drain of the second transistor 240 and are electrically connected to an output line 16.

Next, the detailed configuration of an inverter circuit 210 of the electrophoretic display panel of the embodiment will be described with reference to FIG. 12. FIG. 12 is an enlarged planar diagram of the inverter circuit 210 of the electrophoretic display panel of the embodiment. Here, in FIG. 12, since the size of each layer and each member is set to an extent so that they can be recognized in the diagram, the scale for each layer and each member may differ.

The first transistor 230 is configured by a gate electrode 230b being arranged to face a semiconductor layer 230a through a gate insulating film 230c. The second transistor 240 is configured by a gate electrode 240b being arranged to face a semiconductor layer 240a through a gate insulating film 240c.

The source of the first transistor 230 is electrically connected to the high potential voltage source line 91. The drain of the first transistor 230 is electrically short-circuited to the drain of the second transistor 240 via a first connection line 231. A gate electrode 230b of the first transistor 230 is electrically short-circuited to a gate electrode 240b of the second transistor 240 via a second connection line 232 and is electrically connected to the output line 16. The source of the second transistor 240 is electrically connected to a third connection line 233. The third connection line 233 is electrically connected to the low potential voltage source line 92.

Here, the second connection line 232 is formed to come into direct contact with the gate electrodes 230b and 240b. Also, the third connection line 233 is also formed to come into direct contact with the low potential voltage source line 92. That is, the second connection line 232 and the third connection line 233 of the embodiment are examples of the “connection electrodes” of the invention. Accordingly, since it is not necessary to perform a process of opening contact holes in an insulating film using etching or the like, electrical connection can be realized by fewer processes compared to the case of electrical connection via the contact holes. Furthermore, since it is not necessary to form an insulating film widely on the substrate to form contact holes, it is possible to effectively suppress bending (that is, structural warping) of the element substrate 30.

### Manufacturing Method

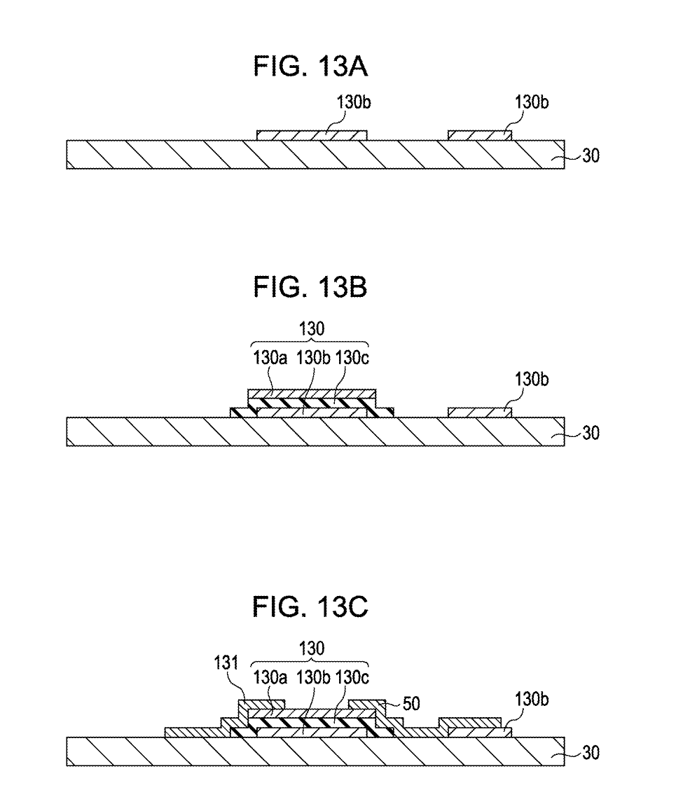

Next, the manufacturing method of the electrophoretic display panel 100 of the first embodiment will be described with reference to FIGS. 13A to 13C. Here, below, mainly the manufacturing method for manufacturing the element substrate 30 side of the electrophoretic display panel 100 of the embodiment will be described.

FIGS. 13A to 13C are process cross-sectional diagrams illustrating a series of manufacturing processes for manufacturing a laminate structure of the peripheral region of the element substrate 30 of the electrophoretic display panel 100 of the embodiment.

First, as shown in FIG. 13A, the element substrate 30 is prepared from, for example, a PET (polyethylene terephthalate) substrate with a thickness. Next, the gate electrode 130b is selectively formed in a required region from a silver paste with a thickness of 500 nm using an ink jet method.

Next, as shown in FIG. 13B, the gate insulating film 130c is formed from polyimide with a thickness of 500 nm using an ink jet method. After that, the semiconductor layer 130a is formed from pentacene with a thickness of 50 nm in the same manner using an ink jet method. The gate insulating film and the capacitance insulating film are selectively formed in a required region.

Next, as shown in FIG. 13C, the data line 50 and the first connection line 131 are formed from a silver paste with a thickness of 300 nm using an ink jet method. The data line 50 is formed to come into direct contact with the gate electrode 130b. Although not shown, the first connection line 131 is formed to come into direct contact with the low potential voltage source line 92. In the embodiment, in particular, it is good if the data line 50 and the first connection line 131 are formed from the same film. In this case, since these various lines can be formed simultaneously in the same process, a reduction in manufacturing processes and lower costs can be achieved. Furthermore, these are also selectively formed in a required region.

Here, although not shown, the gate insulating film and the interlayer insulating film are not also provided at a mounting terminal connecting an external circuit formed in the same layer as the scanning lines 40, the data lines 50 and the like. Also, in the pixel electrode forming process, the mounting terminal may be formed of the same material as the pixel electrode and may be used as a material for performing mounting connection.

By attaching an opposing substrate where an electrophoresis material of a capsule type is held on a transmissive electrode formed from ITO with a thickness of 50 nm on the other substrate formed from a PET substrate with a thickness of 0.5 mm, a driving IC is mounted and the electro-optical device can be formed.

In the above manufacturing method, the pixel electrodes, the connection lines and the line material may use other pastes, organic or inorganic conductive materials or metals. The semiconductor layer may use other organic semiconductor materials or inorganic semiconductor materials. The insulating films may use other organic insulating films or inorganic insulating films. The substrates may use other organic materials or thin inorganic materials. The method for forming thin films may use other printing methods or application methods.

By attaching an electrophoresis sheet, where the electrophoresis element 23 is fixed to the opposing substrate side where the common electrode 22 is formed, is adhered to the element substrate 30 formed in this manner, it is possible to manufacture the electrophoretic display device of the embodiment.

### Electronic Apparatus

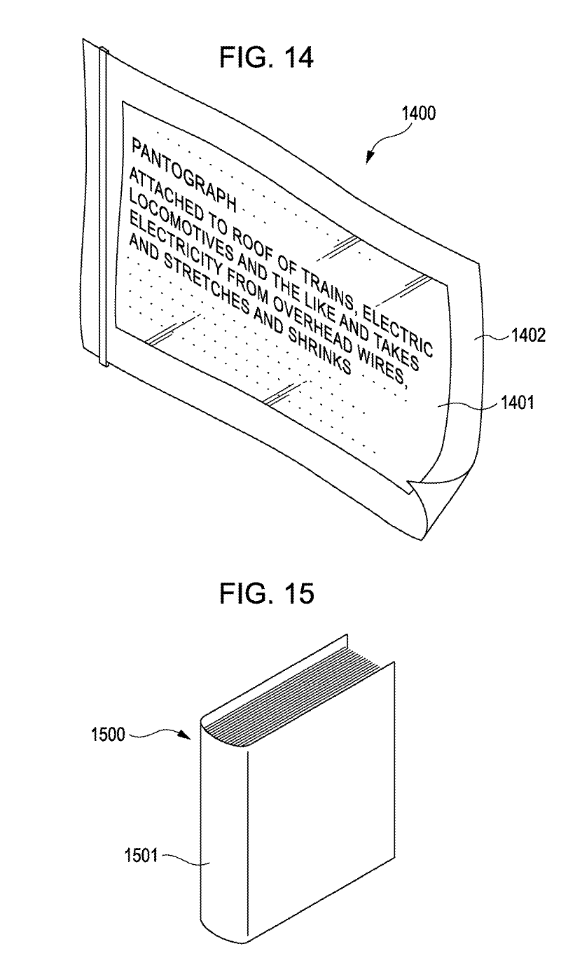

Next, the electronic apparatus applied with the electrophoretic display device described above will be described with reference to FIGS. 14 and 15. Below, the cases where the electrophoretic display device described above is applied to an electronic paper and an electronic notebook are used as examples.

FIG. 14 is a perspective diagram illustrating the configuration of an electronic paper 1400.

As shown in FIG. 14, the electronic paper 1400 is provided with the electrophoretic display device of the invention described above as a display unit 1401. The electronic paper 1400 has flexibility and is configured by being provided with a body 1402 formed of a rewritable sheet having the same feeling and flexibility of existing paper.

FIG. 15 is a perspective diagram illustrating the configuration of an electronic notebook 1500.

As shown in FIG. 15, the electronic notebook 1500 is a binding together of a plurality of sheets of the electronic paper 1400 shown in FIG. 14 which are interposed in a cover 1501. The cover 1501 is provided with a display data input means (not shown) for inputting display data sent from, for example, an external device. Due to this, according to this display data, the display contents can be changed or updated while the electronic paper remains in a bound state.

Since the electronic paper 1400 and the electronic notebook 1500 described above are provided with the electrophoretic display device of the embodiment described above, it is possible to perform a high-quality image display with low consumption of power.

Here, other than these, the electrophoretic display device of the embodiment described above can be applied to the display units of electronic apparatuses such as watches, mobile phones, portable audio devices and the like.

Here, aside from the electrophoretic display panel described in the embodiment described above, the invention can also be applied to liquid crystal displays (LCD), plasma displays (PDP), field emission displays (FED, SED), organic EL displays, digital micromirror devices (DMD), and the like.

The invention is not limited to the embodiments described above, but may be appropriately modified in the scope of the claims and the scope of the concept or the spirit of the invention can be understood from the entire specification. Of course, a substrate for electro-optical devices having such modifications, an electro-optical device having the substrate for electro-optical devices and an electronic apparatus having the electro-optical device are also included in the technical scope of the invention.

What is claimed is:

1. A substrate for electro-optical devices, which has a display region where a plurality of pixels is arranged, comprising:
a substrate,
a pixel electrode provided for each of the pixels on the substrate,
a transistor which is provided more to a lower layer side than the pixel electrode on the substrate and includes a gate insulating film selectively provided in a specific region on the substrate, and
a connection electrode which is arranged more to the upper layer side than the gate insulating film configuring the transistor, is formed to directly overlap with at least a portion of a gate electrode and a source/drain electrode of the transistor in a region where the gate insulating film is not formed on the substrate, and is electrically connected to the transistor.

2. The substrate for electro-optical devices according to claim 1,
wherein, the transistor and the connection electrode are provided for each pixel, and the pixel electrode are formed to overlap with at least the connection electrode in a planar view above the substrate.

3. The substrate for electro-optical devices according to claim 1,
wherein, the transistor is arranged in a peripheral region positioned in the periphery of the display region, and the connection electrode is formed to be diode-connected with the transistors.

4. The substrate for electro-optical devices according to claim 1,
wherein, a plurality of the transistors is provided in the peripheral region positioned in the periphery of the display region, and by being connected to each other by the connection electrode, the plurality of transistors is included in an inverter circuit.

5. The substrate for electro-optical devices according to claim 1,
wherein, the connection electrode is formed by applying a conductive material in a region where the connection electrode is to be formed.

6. The substrate for electro-optical devices according to claim 1,
wherein, a plurality of the transistors is provided in the display region or the peripheral region positioned in the periphery of the display region, and the connection electrode is formed by extending the source electrode or the drain electrode of the transistor.

7. An electro-optical device comprising the substrate for electro-optical devices according to claim 1.

8. An electro-optical device comprising the substrate for electro-optical devices according to claim 2.

9. An electro-optical device comprising the substrate for electro-optical devices according to claim 3.

10. An electro-optical device comprising the substrate for electro-optical devices according to claim 4.

11. An electro-optical device comprising the substrate for electro-optical devices according to claim 5.

12. An electro-optical device comprising the substrate for electro-optical devices according to claim 6.

13. An electronic apparatus comprising the electro-optical device according to claim 7.

14. An electronic apparatus comprising the electro-optical device according to claim 8.

15. An electronic apparatus comprising the electro-optical device according to claim 9.

16. An electronic apparatus comprising the electro-optical device according to claim 10.

17. An electronic apparatus comprising the electro-optical device according to claim 11.

18. An electronic apparatus comprising the electro-optical device according to claim 12.
